(19) United States
(12) Patent Application Publication
(10) Pub. No.: US 2014/0054675 A1
(43) Pub. Date: Feb. 27, 2014

(54) VERTICAL TYPE SEMICONDUCTOR DEVICES AND METHODS OF MANUFACTURING THE SAME

(71) Applicants: Chae-Ho Kim, (US); Sung-Hae Lee, (US); Toshiro Nakanishi, (US); Dong-Woo Kim, (US)

(72) Inventors: Sung-Hae LEE, Gyeonggi-do (KR); Toshiro NAKANISHI, Seongnam-si (KR); Dong-Woo KIM, Incheon (KR); Chae-Ho KIM, Gwangmyeong-si (KR)

(21) Appl. No.: 13/945,336

(22) Filed: Jul. 18, 2013

(30) Foreign Application Priority Data
Aug. 23, 2012 (KR) 10-2012-0092170

(51) Int. Cl. H01L 29/792; H01L 29/66

(52) U.S. Cl. CPC H01L 29/7926; H01L 29/66666; H01L 29/66833
USPC 257/324; 438/269

(57) ABSTRACT

According to example embodiments, a vertical type semiconductor device includes a pillar structure on a substrate. The pillar structure includes a semiconductor pattern and a channel pattern. The semiconductor pattern includes an impurity region. A first word line structure faces the channel pattern and is horizontally extended while surrounding the pillar structure. A second word line structure has one side facing the impurity region of the semiconductor pattern and another side facing the substrate. A common source line is provided at a substrate portion adjacent to a sidewall end portion of the second word line structure.

### CROSS-REFERENCE TO RELATED APPLICATION

This application claims priority under 35 USC §119 to Korean Patent Application No. 10-2012-0092170, filed on Aug. 23, 2012 in the Korean Intellectual Property Office (KIPO), the entire disclosure of which is incorporated herein by reference.

### BACKGROUND

1. Field

Example embodiments relate to vertical type semiconductor devices and/or methods of manufacturing the same. More particularly, example embodiments relate to vertical type NAND flash memory devices and/or methods of manufacturing the same.

2. Description of the Related Art

Recently, a stacking method of cells in a vertical direction with respect to the surface of a substrate has been developed to accomplish a high integration of semiconductor devices. Each transistor included in a vertical type semiconductor device ideally may have a smaller threshold voltage dispersion and may be manufactured by a simple process.

### SUMMARY

Example embodiments relate to a vertical type semiconductor device having an improved characteristic of a ground selection transistor.

Example embodiments also relate to a method of manufacturing a vertical type semiconductor device.

According to example embodiments, a method of manufacturing a vertical type semiconductor device includes: alternately stacking a plurality of sacrificial layers and a plurality of insulating interlayers on a substrate; forming a pillar structure that penetrates the plurality of sacrificial layers and the plurality of insulating interlayers, the pillar structure contacting an upper surface of the substrate, and the pillar structure including a semiconductor pattern and a channel pattern; forming gaps by selectively removing the plurality of sacrificial layers and portions of the plurality of insulating interlayers to expose sidewalls of the semiconductor pattern and the channel pattern; forming an impurity region for controlling a threshold voltage of a lowermost transistor by doping impurities under a surface of the semiconductor pattern that is exposed by one of the gaps; forming a first word line structure and forming a second word line structure; and forming a common source line at a portion of the substrate that is adjacent to a sidewall end portion of the second word line structure. The first word line structure is formed in a different one of the gaps, and the first word line structure faces the channel pattern and surrounds the pillar structure. The second word line structure is formed in the one of the gaps and the second word line structure has one side facing the semiconductor pattern and another side facing the substrate.

In example embodiments, the forming the common source line may include doping impurities into the portion of the substrate that is adjacent to the sidewall end portion of the second word line structure.

In example embodiments, a conductivity type of the impurities in the impurity region may be opposite a conductive type of the impurities in the common source line.

In example embodiments, the forming the impurity region by doping impurities may include doping p-type impurities under the surface of the semiconductor pattern, and the doping impurities of the forming the common source line may be include doping n-type impurities into the portion of the substrate.

In example embodiments, the method may further include doping impurities under a part of the substrate facing the second word line structure, and the impurities under the part of the substrate may have a different conductivity type than the impurities in the impurity region of the semiconductor pattern.

In example embodiments, forming the impurity region by doping impurities under the surface of the semiconductor pattern may include a gas phase doping process.

According to example embodiments, a vertical type semiconductor device includes: a substrate; a pillar structure on the substrate, the pillar structure including a semiconductor pattern and a channel pattern, the semiconductor pattern including an impurity region under a surface of the semiconductor pattern, the impurity region being configured to a control a threshold voltage of a transistor; a first word line structure facing the channel pattern and extending horizontally while surrounding the pillar structure; a second word line structure surrounding the pillar structure, the second word line structure including one side facing the impurity region of the semiconductor pattern and an other side facing the substrate; and a common source line at a portion of the substrate that is adjacent to a sidewall end portion of the second word line structure.

In example embodiments, a conductivity type of the impurity region may be opposite a conductivity type of the impurities in the common source line.

In example embodiments, one of an undoped region and an impurity doped region may be under a surface of the substrate, and the one of the undoped region and the impurity doped region may face the second word line structure. A conductivity type of the impurity doped region may be the same as a conductivity type as the impurity region in the semiconductor pattern.

In example embodiments, an impurity doped region having an opposite conductive type to the impurity region in the semiconductor pattern may be further included under the surface of the substrate and face the second word line structure.

According to example embodiments, a vertical type semiconductor type includes: a substrate including a common source line (CSL); a pillar extending vertically from a portion of the substrate; and a plurality of word line structure and insulating interlayers alternately stacked on a part of the substrate that is between the portion of the substrate and the CSL. The pillar includes a channel pattern on a semiconductor pattern. The semiconductor pattern includes an impurity region at a sidewall. The impurity region and the CSL have opposite conductivity types. The plurality of word line structures include: a first word line structure extending horizontally from a sidewall of the channel pattern; and a second word line structure that extends horizontally from the impurity region of the semiconductor pattern over a part of the substrate that is between the CSL and the portion of the substrate.

In example embodiments, the second word line structure may be on a pad oxide layer. The second word line structure may include a metal layer and a dielectric layer. The dielectric layer may be between the metal layer and the impurity region of the semiconductor pattern. The metal layer may be configured as a gate of a vertical transistor that includes the impurity region of the semiconductor pattern as a channel. The metal layer may also be configured as a gate of a planar transistor that includes the part of the substrate as a channel region.

In example embodiments, the substrate may further include an impurity doped region that extends into the portion of the substrate and the part of the substrate. A conductivity type of the impurity doped region may be opposite the conductivity type of the impurity region in the semiconductor pattern.

In example embodiments, the substrate may further include an undoped impurity doped region that extends into the portion of the substrate and the part of the substrate.

In example embodiments, the substrate further may include a doped impurity doped region that extends into the portion of the substrate and the part of the substrate. A conductivity type of the impurity doped region is the same as the conductivity type of the impurity region in the semiconductor pattern. An impurity concentration of the impurity doped region is lighter than that of the impurity region in the semiconductor pattern.

In example embodiments, the impurity region may be positioned at a surface portion of the semiconductor pattern.

In example embodiments, an impurity concentration of a surface portion of the semiconductor pattern may be higher than that of an inner portion of the semiconductor pattern.

In example embodiments, a pad may be on the channel pattern, the first word line structure may be a string selection line, and the plurality of word line structures may include other word line structure between the first word line structure and the second word line structure.

In example embodiments, a charge storing layer may surround the channel pattern, a tunnel insulating layer may surround the charge storing layer, and the tunnel insulating layer may be between the channel pattern and other word line structures.

In a vertical type semiconductor device according to example embodiments, a ground selection transistor may be manufactured by a simple process, and threshold voltage dispersion may be improved.

### BRIEF DESCRIPTION OF THE DRAWINGS

Example embodiments will be more clearly understood from the more particular description of non-limiting embodiments, as illustrated in the accompanying drawings, in which like reference characters refer to the same parts throughout the different views. The drawings are not necessarily to scale, emphasis instead being placed upon illustrating the features of example embodiments. In the drawings:

FIG. 1 is a cross-sectional view illustrating a vertical type semiconductor device in accordance with Example 1;

FIG. 2 is an enlarged diagram on part A in FIG. 1;

FIGS. 3A to 3G are cross-sectional views for explaining a method of manufacturing the vertical type semiconductor device illustrated in FIGS. 1 and 2;

FIG. 4 is a cross-sectional view illustrating a vertical type semiconductor device in accordance with Example 2;

FIG. 5 is an enlarged diagram on part D in FIG. 4;

FIGS. 6A to 6C are cross-sectional views illustrating a method of manufacturing the vertical type semiconductor device in FIGS. 4 and 5; and

FIG. 7 is a graph illustrating each an impurity concentration according to positions of a semiconductor pattern for Samples 1 to 3 and Comparative Sample.

### DETAILED DESCRIPTION OF THE EMBODIMENTS

Various example embodiments will be described more fully hereinafter with reference to the accompanying drawings, in which some example embodiments are shown. Example embodiments of inventive concepts may, however, be embodied in many different forms and should not be construed as limited to the embodiments set forth herein. Rather, these example embodiments are provided so that this description will be thorough and complete, and will fully convey the scope of example embodiments of inventive concepts to those skilled in the art. In the drawings, the sizes and relative sizes of layers and regions may be exaggerated for clarity. Like reference numerals in the drawings denote like elements, and thus their description may be omitted.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Other words used to describe the relationship between elements or layers should be interpreted in a like fashion (e.g., “between” versus “directly between,” “adjacent” versus “directly adjacent,”). As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,”, “includes” and/or “including”, when used in this specification, specify the presence of stated features, integers, steps, operations, elements, and/or components, but do not preclude the presence or addition of one or more other features, integers, steps, operations, elements, components, and/or groups thereof. Expressions such as “at least one of,” when preceding a list of elements, modify the entire list of elements and do not modify the individual elements of the list.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which example embodiments of inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be described in detail with reference to the accompanying drawings.

### Example 1

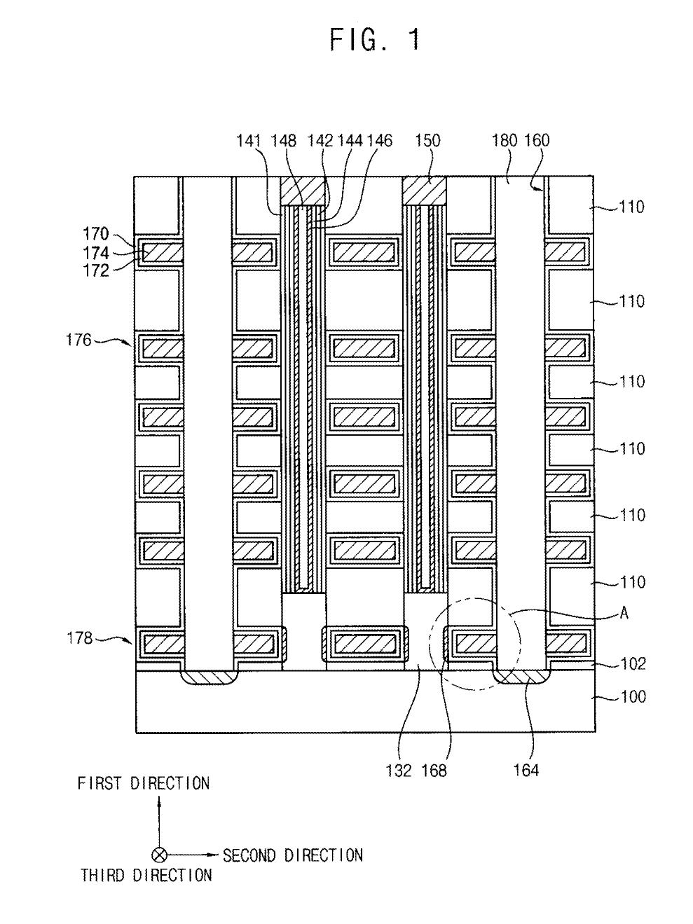

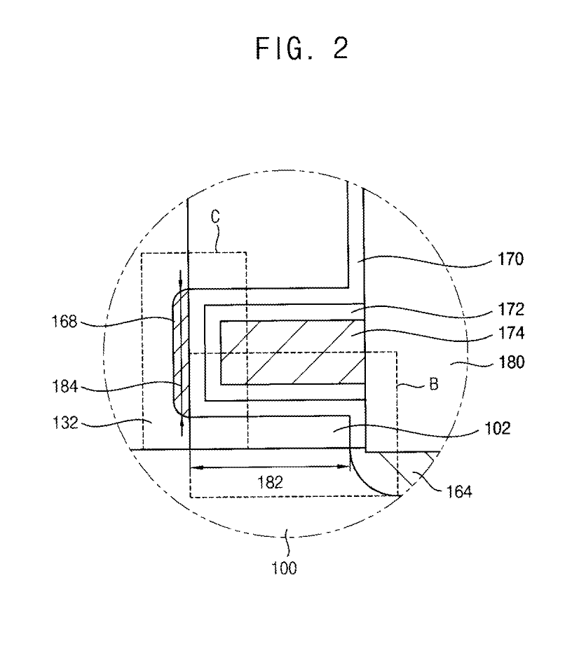

FIG. 1 is a cross-sectional view illustrating a vertical type semiconductor device in accordance with Example 1. FIG. 2 is an enlarged diagram on part A in FIG. 1.

Hereinafter, a direction perpendicular to the upper surface of a substrate may be defined as a first direction, a direction in parallel with the upper surface of the substrate and perpendicular to the extending direction of a word line may be defined as a second direction, and the extending direction of the word line may be defined as a third direction.

Referring to FIGS. 1 and 2, a vertical type semiconductor device may include a pillar structure including a semiconductor pattern 132 extruded and extended in the first direction on a substrate 100, a channel pattern 146, and extruded and extended in the first direction on the semiconductor pattern 132, a first burying insulating layer pattern 148 filling up the inner space of the channel pattern 146, and a tunnel insulating layer 144, a charge storing layer 142 and a sacrificial oxide layer 141 stacked one by one so as to surround the outer wall of each channel pattern 146. A first word line structure 176 extended while surrounding the sidewall of the channel pattern 146 and a second word line structure 178 extended while surrounding the sidewall of the semiconductor pattern 132 also may be provided. The second word line structure 178 may be provided as the gate of a ground selection transistor. Under the surface of the semiconductor pattern 132 facing the second word line structure 178, a p-type impurity region 168 may be provided. The p-type impurity region 168 may be provided as an impurity region for controlling the threshold voltage of the ground selection transistor. The vertical memory device may further include a common source line (CSL) 164 and a bit line (not illustrated). The channel pattern 146 may have a cylindrical shape, but example embodiments are not limited thereto.

The substrate 100 may include, for example, a semiconductor material such as silicon and germanium.

The semiconductor pattern 132 may make a contact with the surface of the substrate 100 and may be extruded from the surface of the substrate 100 to have a pillar shape. The semiconductor pattern 132 may include single crystalline silicon. The semiconductor pattern 132 may be doped with impurities, or undoped. The semiconductor pattern 132 may be provided as the channel layer of the ground selection transistor.

The channel pattern 146 may make contact with the upper surface of the semiconductor pattern 132 and may be extruded to have a cylinder shape. As described above, the first burying insulating layer pattern 148 may fill up the inner space of the channel pattern 146 of the cylinder shape. Alternatively, the channel pattern 146 may have a cylinder shape to completely fill up the inner portion of a channel hole, and/or the channel pattern 146 may have a shape other than a cylinder. The channel pattern 146 may include polysilicon or single crystalline silicon. The channel pattern 146 may doped with impurities or the channel pattern 146 may be undoped.

The tunnel insulating layer 144 may have a shape surrounding the outer wall of the channel pattern 146. The tunnel insulating layer 144 may include an oxide such as silicon oxide.

The charge storing layer 142 may be provided on the tunnel insulating layer 144 and may further include a nitride such as silicon nitride.

On the pillar structure, a pad 150 may be disposed. The pad 150 may include polysilicon or single crystalline silicon doped or undoped with impurities. The pad 150 may make an electric contact with the channel pattern 146.

The first word line structures 176 may be disposed so as to face the portion of the channel pattern 146. The first word line structures 176 may fill up a gap portion between insulating interlayers 110 at each layer in the first direction. The first word line structure 176 may include a blocking dielectric layer 170, a barrier metal layer 172 and a metal layer 174 and may include a stacked structure thereof.

The blocking dielectric layer 170 may include silicon oxide and/or a metal oxide having a higher electric constant than the silicon oxide. Example of materials used for the metal oxide may include an oxide of aluminum, an oxide of hafnium, an oxide of lanthanum, an oxide of lanthanum aluminum, an oxide of lanthanum hafnium, an oxide of hafnium aluminum, an oxide of titanium, an oxide of tantalum, an oxide of zirconium, but example embodiments are not limited thereto. The above materials can be used alone or in a combination thereof.

The barrier metal layer 172 and the metal layer 174 may be provided as the gate of each transistor. In addition, the gate may be extended in the third direction and may function as a word line. The barrier metal layer 172 may include a conductive metal nitride such as, for example, titanium nitride, tantalum nitride, etc. The metal layer 174 may include a metal having a low electric resistance such as tungsten, titanium, tantalum, platinum, etc. In example embodiments, the metal layer 174 may include tungsten.

Particularly, the gate electrode at the first or second floor formed at the upper portion of the pillar structure among the first word line structures 176 may be provided as a string selection line (SSL).

The second word line structure 178 may be provided as a GSL. The second word line structure 178 may also include the blocking dielectric layer 170, the barrier metal layer 172 and the metal layer 174, and may have a stacked structure thereof as in the first word line structure 176.

The second word line structure 178, the substrate 100 and the semiconductor pattern 132 may be provided as the ground selection transistor. Hereinafter, referring to FIG. 2, the ground selection transistor will be described in detail.

The ground selection transistor may include a connection structure of a planar transistor B including a horizontal channel region and a vertical transistor C including a vertical channel region in series. Below, the ground selection transistor may be explained for an NMOS transistor.

The metal layer 174 included in the second word line structure 178 may include a portion facing the surface of the substrate 100 and a portion facing the sidewall of the semiconductor pattern 132. The portion of the substrate 100 facing the metal layer 174 may be a first channel region 182, which may be a horizontal channel region. A, portion of the semiconductor pattern may be a second channel region 184, which may be a vertical channel region, and may face the metal layer 174. In addition, a pad oxide layer 102 may be disposed on the substrate 100. The pad oxide layer 102 may be provided as a portion of a gate insulating layer of the planar transistor B.

The first channel region 182 may maintain an impurity undoped state or an initially doped state of the substrate 100. When the initial substrate is lightly doped with p-type impurities, the first channel region 182 may be a p-type impurity doped state lighter than the second channel region.

The second channel region 184 may be a p-type impurity doped state heavier than the first channel region 182. That is, a p-type impurity region 168 may be provided in the second channel region 184. The p-type impurity region 168 may be provided as an impurity region for controlling a threshold voltage to control the threshold voltage of the ground selection transistor. The p-type impurity region 168 may become the impurity region for controlling the threshold voltage to control the threshold voltage of the vertical type transistor included in the ground selection transistor.

Accordingly, the planar transistor B including the horizontal channel region in the ground selection transistor may not be separately doped with impurities for controlling the threshold voltage and may have a relatively low threshold voltage to be provided as a pass transistor. The vertical transistor C including the vertical channel region in the ground selection transistor may have a relatively high threshold voltage to be provided as a selection transistor substantially functioning as a switch.

In example embodiments, when the ground selection transistor is PMOS transistor, an n-type impurity region 168 may be provided in the second channel region 184. The n-type impurity region 168 may be provided as an impurity region for controlling a threshold voltage to control the threshold voltage of the ground selection transistor. In addition, the first channel region 182 may be doped with n-type impurities at a lighter concentration than the second channel region 184. Alternatively, the first channel region 182 may be undoped.

The impurity region 168 for controlling the threshold voltage may be doped with impurities of opposite type to the conductive type of the ground selection transistor. Accordingly, the impurity region 168 for controlling the threshold voltage may be doped with impurities of opposite type to the impurity type of the CSL.

As described above, the vertical type transistor C including the vertical channel region may be provided as a substantial selection transistor in the ground selection transistor. Therefore, a short channel effect frequently generated when using the planar transistor B as the substantial selection transistor may be decreased. In addition, even though the length of the second word line structure along the side portion thereof may not be uniform, the characteristic difference of the ground selection transistor due to the non-uniformity may be reduced.

Since the pad oxide layer is not used as the gate insulating layer of the vertical type transistor, damage generated onto the pad oxide layer may not change the characteristics of the ground selection transistor. Accordingly, the threshold voltage dispersion due to the damage of the pad oxide layer may be reduced (and/or minimized).

Therefore, the threshold voltage dispersion of the ground selection transistor may be improved and a good electric character may be obtained.

Between the first and second word line structures 176 and 178 and the structures of stacked insulating interlayers 110, an opening portion 160 of a trench shape may be disposed. The inner portion of the opening portion 160 may be filled up with a second burying insulating layer pattern 180.

On the upper portion of the substrate 100 under the second burying insulating layer pattern 180, a CSL 164 extended in the third direction may be disposed. The CSL may be formed as an impurity region. The impurity region may include n-type impurities such as phosphorus and arsenic. Even though not illustrated, a metal silicide pattern such as a cobalt silicide pattern, a nickel silicide pattern, etc. may be further formed on the impurity region. The CSL 164 may be provided as a common source of each of the ground selection transistors.

The bit line (not illustrated) may make electric contact with the pad 150 by a bit line contact. Accordingly, the bit line may make electric contact with the channel pattern 146. The bit line may include a metal, a metal nitride, doped polysilicon, etc.

In example embodiments, the first and second word line structures 176 and 178 in the vertical type semiconductor device may include the blocking dielectric layer 170, the barrier metal layer 172 and the metal layer 174, respectively. In addition, the pillar structure may include the semiconductor pattern 132, the channel pattern 146, the first burying insulating layer pattern 148 filling up the inner space of the channel pattern 146, the tunnel insulating layer 144 stacked one by one so as to surround the outer wall of each channel pattern 146, the charge storing layer 142 and the sacrificial oxide layer 141.

However, the first and second word line structures 176 and 178 and the pillar shape and the stacked structure may not be limited to the above-described embodiments but may be diversely altered. Particularly, the first and second word line structures 176 and 178 may include the tunnel insulating layer, the charge storing layer, the blocking dielectric layer, the barrier metal layer and the metal layer. In this case, the pillar structure may include the semiconductor pattern, the channel pattern and the first burying insulating layer pattern filling up the inner space of the channel pattern.

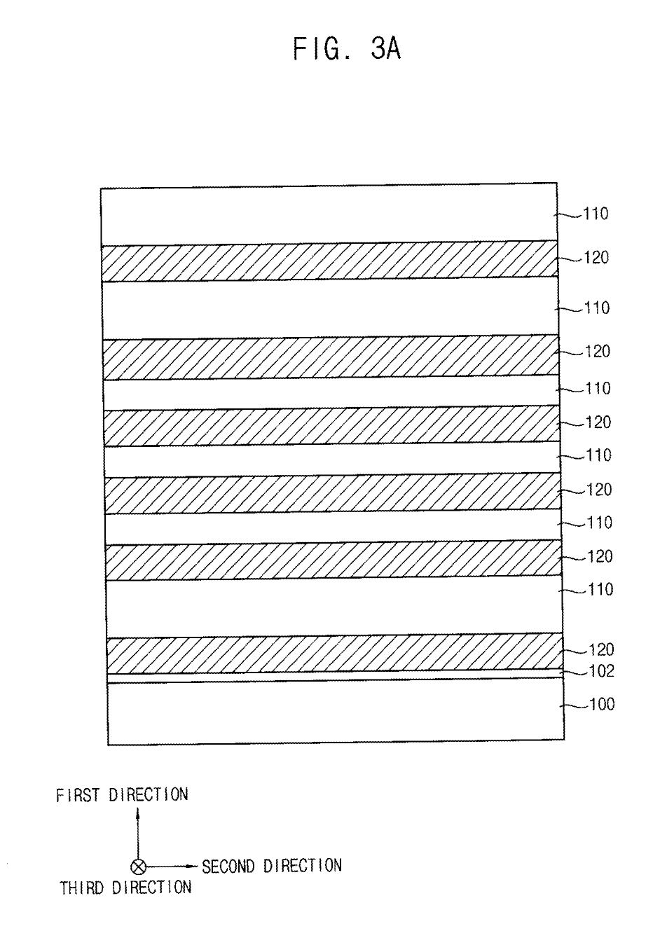

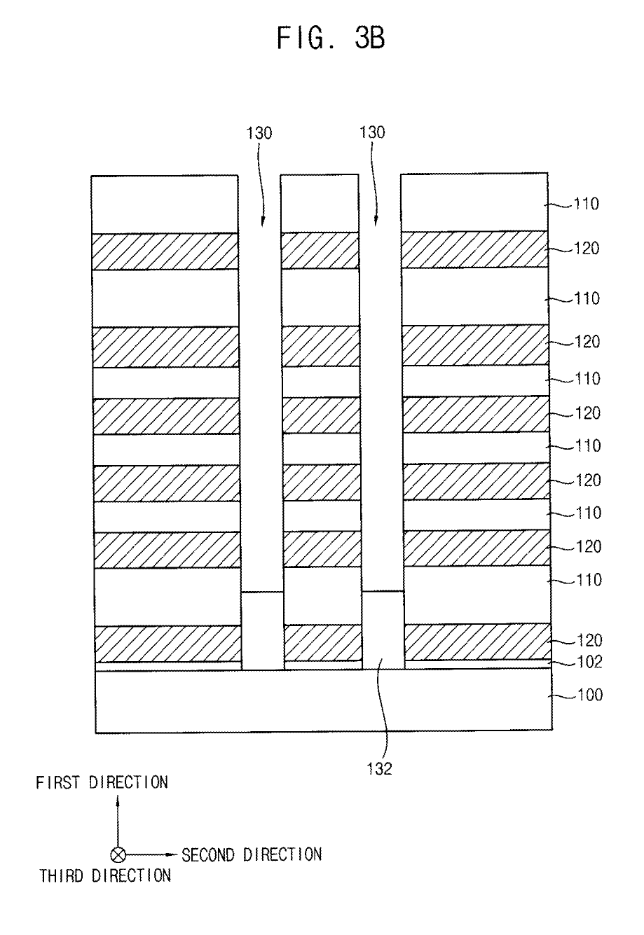

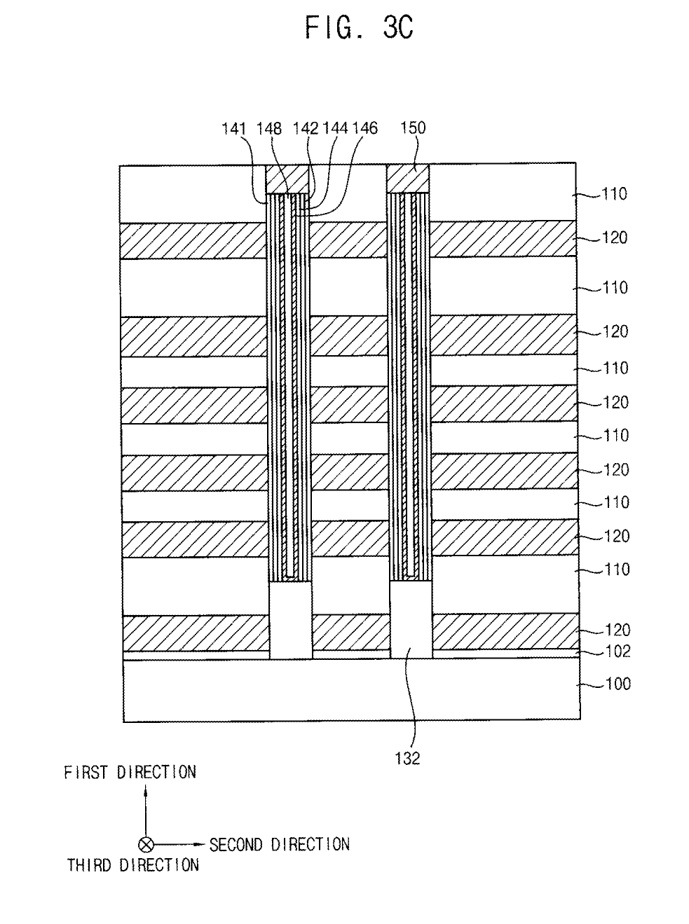

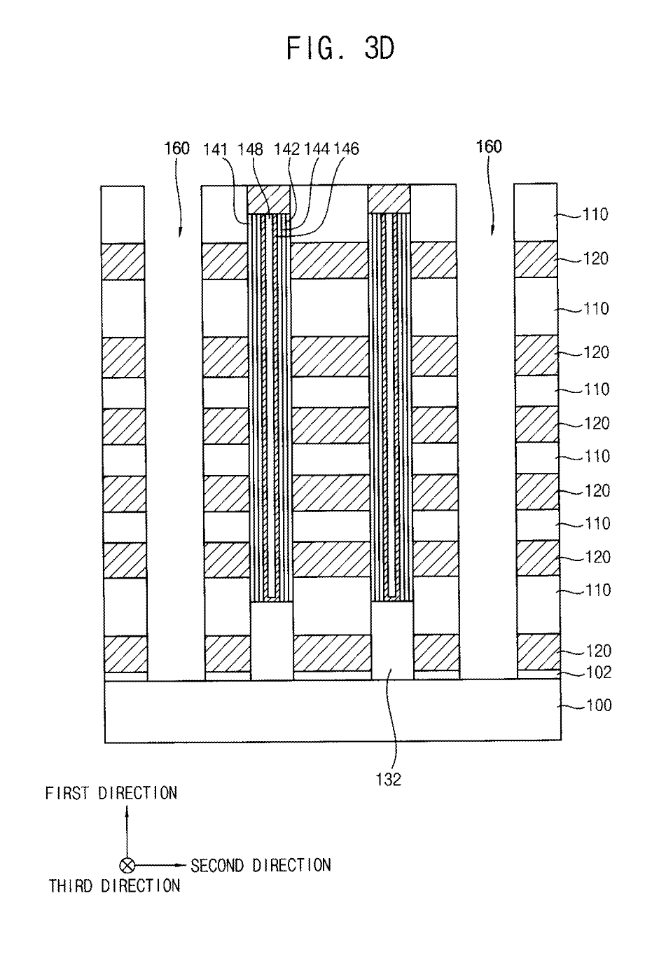

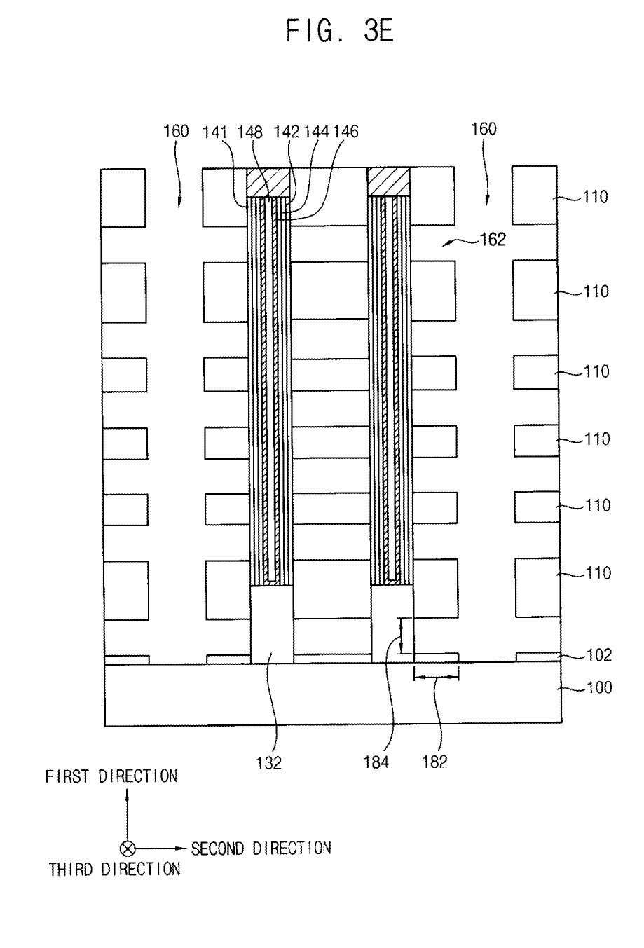

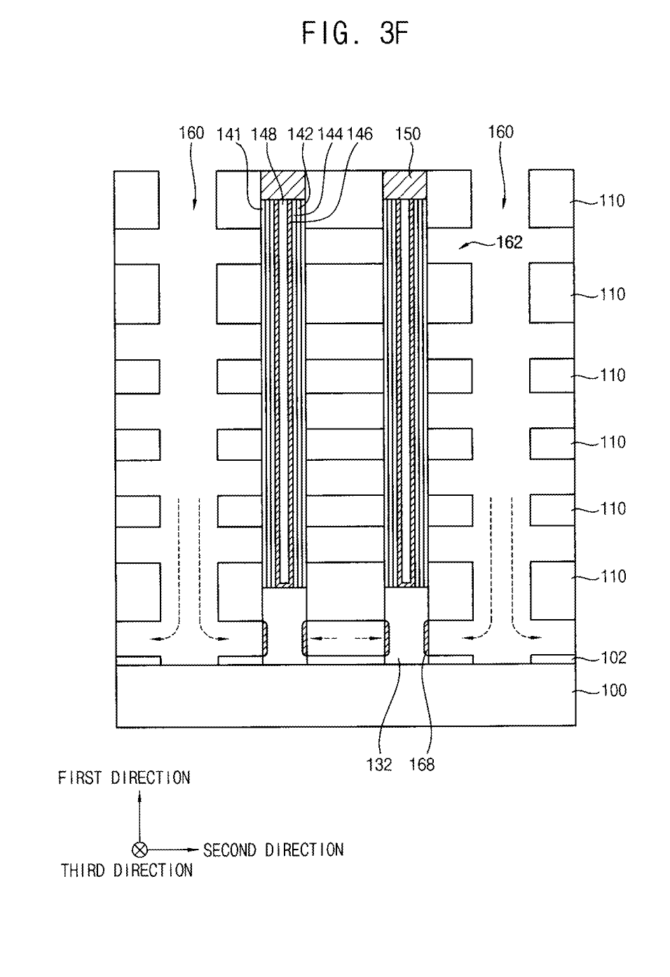

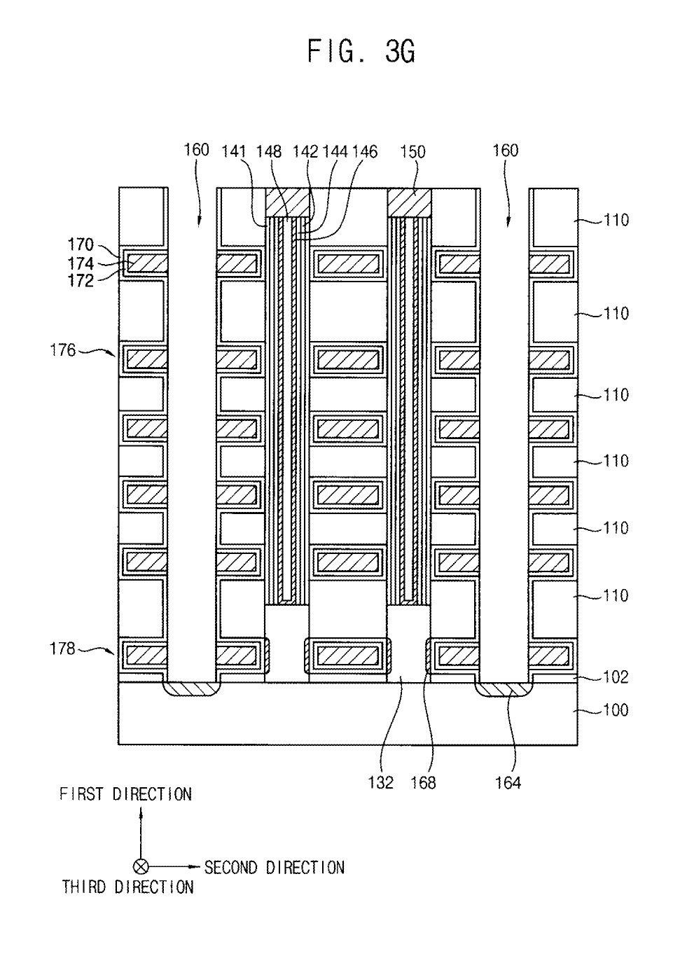

FIGS. 3A to 3G are cross-sectional views for explaining a method of manufacturing the vertical type semiconductor device illustrated in FIGS. 1 and 2.

Referring to FIG. 3A, a pad oxide layer 102 may be formed on a substrate 100.

The substrate 100 may include a semiconductor material such as silicon, germanium, etc. The substrate 100 may be lightly doped with p-type impurities.

The pad oxide layer 102 may be provided as a portion of a gate insulating layer of a planar transistor (see FIG. 2, B) included in a ground selection transistor. The pad oxide layer 102 may be a silicon oxide layer formed by thermally oxidizing the substrate. Alternatively, the pad oxide layer 102 may be an oxide of silicon formed by other processes such as a chemical vapor deposition process.

In example embodiments, an ion doping process may not be conducted after forming the pad oxide layer 102. That is, a channel doping for controlling a threshold voltage may not be conducted into the portion of the substrate 100 disposed under the pad oxide layer 102 of the ground selection transistor.

On the pad oxide layer 102, sacrificial layers 120 and insulating interlayers 110 may be alternately and repeatedly stacked. The sacrificial layers 120 and the insulating interlayers 110 may be formed by a chemical vapor deposition (CVD) process, a plasma enhanced chemical vapor deposition (PECVD) process, an atomic layer deposition (ALD) process, etc. The insulating interlayer 110 may be formed by using silicon oxide, and the sacrificial layer 120 may be formed by using a material having an etching selectivity with respect to the insulating interlayer 110, for example, silicon nitride.

Through a subsequent process, the gate of the transistor of each layer may be formed in the sacrificial layer 120 of each layer. Particularly, the sacrificial layer 120 of the first floor or the second floor at the upper portion among the sacrificial layer 120 of each layer, may be a mold layer for forming the SSL. The sacrificial layer 120 of the first floor or the second floor at the lower portion among the sacrificial layer 120 of each layer, may be a mold layer for forming the GSL. In addition, the sacrificial layers 120 disposed between the mold layers for forming the SSL and GSL may be mold layers for forming cell transistors. Therefore, the number of stacking of the insulating interlayers 110 and the sacrificial layers 120 may be increased or decreased according to the number of the transistors stacked in the first direction. In this case, the sacrificial layer 120 of the first floor or the second floor at the lower portion may be formed to a thickness of the length of the vertical gate of the GSL to be formed.

Referring to FIG. 3B, a plurality of channel holes 130 penetrating the insulating interlayers 110 and the sacrificial layers 120 to expose the upper surface of the substrate 100 may be formed. The channel holes 130 may be formed by a dry etching process, in which a hard mask 140 may be formed on the uppermost insulating interlayer 110 and the hard mask 140 may be used as an etching mask. Each of the channel holes 130 may be formed to have a narrowing width in line with the depth thereof according to the characteristic of the dry etching process.

A plurality of the channel holes 130 may be formed in the second direction and in the third direction, respectively. Accordingly, a hole array may be defined.

A semiconductor pattern 132 partially filling up the lower portion of each channel hole 130 may be formed. Particularly, a selective epitaxial growth (SEG) process using the upper surface of the exposed substrate 100 through the channel hole 130 as a seed may be conducted to form the semiconductor pattern 132 partially filling up the bottom portion of the channel hole 130. The semiconductor pattern 132 may be formed to include single crystalline silicon or single crystalline germanium. The semiconductor pattern 132 may be provided as a channel layer of the ground selection transistor. Accordingly, the semiconductor pattern 132 may be formed to have an upper surface that is higher than the upper surface of an adjacent one of the sacrificial layers 120 that may be a floor for forming the GSL.

Referring to FIG. 3C, on the inner wall of the channel holes 130, on the upper surface of the semiconductor pattern 132 and on the upper surface of the hard mask, a sacrificial oxide layer 141, a charge storing layer 142, a tunnel insulating layer 144 and a first polysilicon layer may be formed one by one. In addition, an oxide of silicon and a nitride of silicon may be further formed on the first polysilicon layer. In this case, the oxide of silicon and the nitride of silicon may be formed as a layer for passivating the first polysilicon layer. The thin layers may be formed along the profile of the inner surface of the channel holes 130 and may not completely fill up the channel holes 130. That is, a space may remain in the channel hole 130 after forming the thin layers.

The charge storing layer 142 may be formed by using a nitride such as the nitride of silicon. The tunnel insulating layer 144 may be formed by using an oxide such as the oxide of silicon.

The first polysilicon layer may be provided as a portion of a channel pattern through conducting a subsequent process. The first polysilicon layer may be doped with impurities. Alternatively, the first polysilicon layer may be undoped.

The bottom portions of the sacrificial oxide layer 141, the charge storing layer 142, the tunnel insulating layer 144 and the first polysilicon layer may be etched to expose the upper portion of the semiconductor pattern 132. Through conducting the etching process, the first polysilicon layer, the tunnel insulating layer 144, the charge storing layer 142 and the sacrificial oxide layer 141 may remain on the sidewall of the channel hole 130 as a spacer shape. When the oxide of silicon and the nitride of silicon are formed on the first polysilicon layer in a previous process, the oxide of silicon and the nitride of silicon may be removed together during the etching process.

After that, a second polysilicon layer may be formed on the surface of the first polysilicon layer and the semiconductor pattern 132. The first and second polysilicon layers may be provided as a channel pattern 146. The channel pattern 146 may make contact with the semiconductor pattern 132 and may have a cylinder shape.

An insulating layer may be formed to completely fill up the inner portion of the channel hole 130, and the insulating layer may be polished to form a first burying insulating layer pattern 148. The first burying insulating layer pattern 148 may include an oxide of silicon.

Subsequently, a portion of the upper portion of the first burying insulating layer pattern 148 may be removed to form an opening portion. A polysilicon layer may be formed in the opening portion and may be polished to form a pad 150. Through conducting the above described processes, a pillar structure may be completed in the channel hole 130.

Referring to FIG. 3D, openings 160 penetrating the insulating interlayers 110, the sacrificial layers 120 and the pad oxide layer 102 may be formed to expose the upper surface of the substrate 100.

The openings 160 may define the gap portion between the word line structures. The openings 160 may be formed to be extended in the third direction. In addition, a plurality of the openings 160 may be formed along the second direction. Through forming the opening portion 160, the insulating interlayers 110 and the sacrificial layers 120 may have a patterned shaped.

Referring to FIG. 3E, the sacrificial layer 120 of each layer exposed to the sidewall of the opening 160 may be removed to form a gap 162 between the insulating interlayers 110 and the pad oxide layer. The removing process of the sacrificial layers 120 may be conducted through a wet etching process using an etching solution having a higher etching selectivity with respect to the insulating interlayer 110. The etching solution may include phosphoric acid. In the gap, the surface of the sacrificial oxide layer 141 may be exposed.

In addition, through removing the sacrificial layer 120 positioned at the lower portion, a portion of the outer sidewall of the semiconductor pattern 132 may be exposed. The exposed semiconductor pattern 132 may become a second channel region 184, which may be a vertical direction channel region of the ground selection transistor.

The ground selection transistor may include a first channel region 182, which may be a portion of the substrate 100 under the pad oxide layer 102 in a horizontal direction and the second channel region 184, which may be the sidewall portion of the semiconductor pattern 132 in a vertical direction. Accordingly, the ground selection transistor may have a connected structure of a planar transistor including the first channel region 182 and a vertical transistor including the second channel region 184.

Referring to FIG. 3F, p-type impurities may be doped into the exposed surface of the semiconductor pattern around the gap 162. The doping process of the p-type impurities may include a gas phase doping process. That is, by introducing and providing a gas source including the p-type impurities, the p-type impurities may be doped into the surface of the exposed semiconductor pattern 132.

Through doping the p-type impurities into the surface of the semiconductor pattern, a p-type impurity region 168 may be formed in the second channel region of the ground selection transistor. That is, the second channel region may have the p-type impurity concentration heavier than the first channel region. The p-type impurity region 168 may be provided as an impurity region for controlling the threshold voltage to control the threshold voltage of the ground selection transistor.

In example embodiments, in the impurity ion doping process to control the threshold voltage, a preliminary process including the formation of a buffer layer may not be necessary before conducting the impurity ion doping process. Only the p-type impurity doping process may be additionally conducted after forming the gap 162. Accordingly, the threshold voltage of the ground selection transistor may be easily controlled through a simple process.

The gas source used in the doping process may include BF₂. The doping process may be conducted with a boron concentration of about 1E20 atoms/cm³ to about 1E18 atoms/cm³. However, the condition of the gas phase doping process may be changed according to a target threshold voltage and may not be limited to the above value.

After conducting the doping process, a thermal treatment may be further conducted to diffuse the doped impurities. Particularly, the heat treatment may be conducted at 600° C. to 850° C. for 10 to 30 minutes. Alternatively, the doped impurities may be diffused while conducting a subsequent process and the heat treatment may be omitted.

In example embodiments, the threshold voltage of the ground selection transistor may be controlled not by the planar transistor part but by the vertical transistor part. Therefore, the process conducted for controlling the threshold voltage at the planar transistor part, for example, the forming and removing process of a buffer layer for doping ions, an impurity doping process, etc. may be omitted. Accordingly, the ground selection transistor may be formed through a more simplified process.

An example has been explained where the ground selection transistor is an NMOS transistor. Alternatively, n-type impurities may be doped during the doping process to form an impurity region for controlling the threshold voltage when the ground selection transistor is a PMOS transistor.

As described above, the impurity region 168 for controlling the threshold voltage may be doped with impurities having an opposite conductive type to the impurities of a CSL to be formed subsequently.

Even though not illustrated, after conducting the impurity doping process, a selective removing process of the sacrificial oxide layer 141 exposed to the inner portion of the gap may be further included.

Referring to FIG. 3G, a blocking dielectric layer 170 may be formed in the gap 162. The blocking dielectric layer 170 may be formed by stacking a silicon oxide layer and a metal oxide layer having a higher electric constant than the silicon oxide layer. Examples of materials used for the metal oxide layer may be include an oxide of aluminum, an oxide of hafnium, an oxide of lanthanum, an oxide of lanthanum aluminum, an oxide of lanthanum hafnium, an oxide of hafnium aluminum, an oxide of titanium, an oxide of tantalum, an oxide of zirconium, etc. The above materials may be used alone or in a combination thereof.

A barrier metal layer 172 may be formed on the blocking dielectric layer 170, and a metal layer 174 completely filling up the gap 162 portion may be formed. The barrier metal layer 172 and the metal layer 174 may be provided as a word line in a subsequent process. The barrier metal layer 172 may be formed by using a metal nitride such as a nitride of titanium and a nitride of tantalum. The metal layer 174 may be formed by using a metal having a low electric resistance such as tungsten, titanium, tantalum, platinum, but example embodiments are not limited thereto.

Then, the metal layer 174 and the barrier metal layer 172 formed in the opening portion 160 may be removed to form first and second word line structures 176 and 178 in the gap 162, respectively. The removing process may include a wet etching process.

The second word line structure 178 may be provided as the gate of the ground selection transistor. The portion facing the substrate 100 may be provided as the gate of the planar transistor, and the portion facing the semiconductor pattern 132 may be provided as the gate of the vertical transistor in the second word line structure 178. In the ground selection transistor, impurities for controlling a threshold voltage may not be separately doped into the channel region of the planar transistor (see FIG. 2, B). Accordingly, the planar transistor may have a relatively low threshold voltage and may be provided as a pass transistor. Differently, the channel region of the vertical transistor in the ground selection transistor may be doped with impurities for controlling the threshold voltage. Accordingly, the vertical transistor may have a relatively high threshold voltage, and may be provided as a selection transistor substantially functioning as a switch.

After that, impurities may be doped into the upper surface of the exposed substrate 100 to form an impurity region provided as a CSL 164. The impurities may include n-type impurities such as phosphorus and arsenic. The CSL may have the impurity region having a shape extended in the third direction.

Even not illustrated, on the impurity region provided as the CSL 164, a metal silicide pattern such as a cobalt silicide pattern or a nickel silicide pattern may be further formed.

Referring to FIG. 1 again, a second burying insulating layer pattern 180 filling up the opening portion 160 may be formed. Then, an upper insulating interlayer may be formed on the thus formed structures, and contact holes exposing the upper surface of a pad 150 may be formed, even not illustrated. A bit line contact may be formed in the contact holes, and a bit line making contact with the upper portion of the bit line contact may be formed.

According to example embodiments, the threshold voltage of the ground selection transistor may be controlled through a simplified process. Therefore, the manufacturing process of a vertical type non-volatile memory device may be simplified.

### Example 2

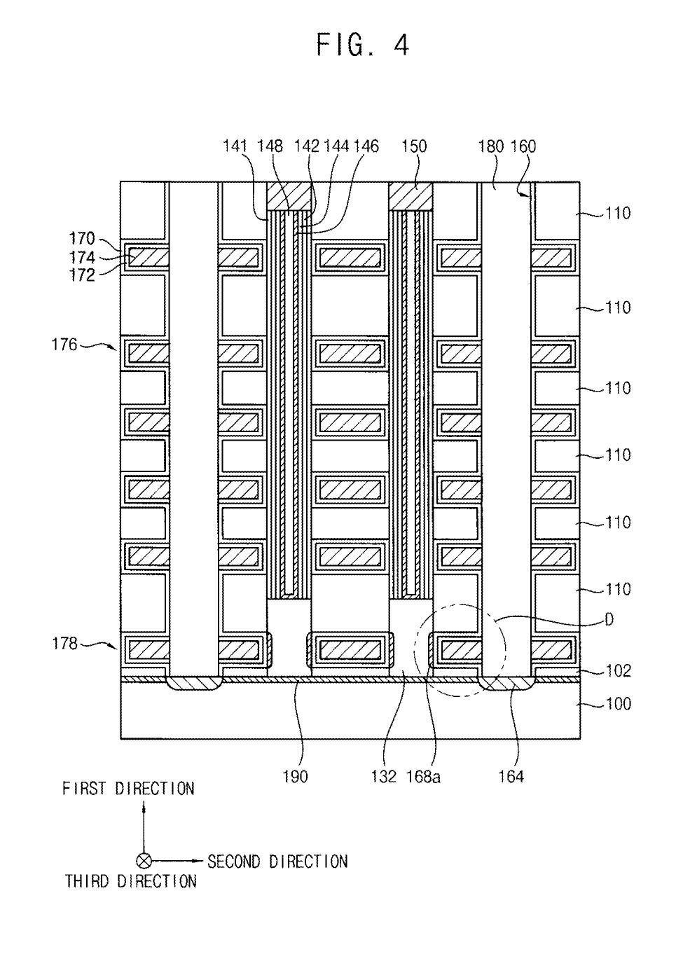

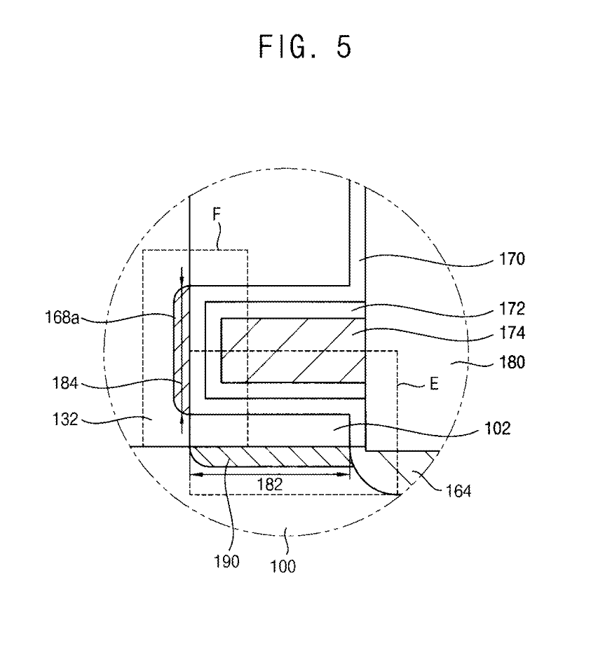

FIG. 4 is a cross-sectional view illustrating a vertical type semiconductor device in accordance with Example 2. FIG. 5 is an enlarged diagram on part D in FIG. 4.

The vertical type semiconductor device in Example 2 may be the same as the vertical type semiconductor device in Example 1 except for the impurity doped region in the channel region of a ground selection transistor. Therefore, explanation will be given mainly on difference points from the vertical type semiconductor device in Example 1.

Referring to FIGS. 4 and 5, a vertical type memory device may include a pillar structure including a semiconductor pattern 132 extruded and extended in a first direction on a substrate 100, a channel pattern 146 having a cylinder shape, and extruded and extended in the first direction on the semiconductor pattern 132, a first burying insulating layer pattern 148 filling up an inner space of the channel pattern 146, and a tunnel insulating layer 144, a charge storing layer 142 and a sacrificial oxide layer 141 formed one by one so as to surround the outer wall of each channel pattern 146. A first word line structure 176 extended while surrounding the sidewall of the channel pattern 146 and a second word line structure 178 extended while surrounding the sidewall of the semiconductor pattern 132 may also be provided. The second word line structure 178 may be provided as the gate of a ground selection transistor.

As illustrated in FIG. 5, a portion around the second word line structure 178, the substrate 100 and the semiconductor pattern 132 may be provided as the ground selection transistor. The ground selection transistor may have a connected structure of a planar transistor E having a horizontal channel region and a vertical transistor F having a vertical channel region. In example embodiments, the ground selection transistor may be an NMOS transistor. An explanation for when the ground selection transistor is an NMOS transistor is provided below.

Under the surface of the semiconductor pattern 132, facing the second word line structure 178, a p-type impurity region 168a may be provided. The p-type impurity region 168a may be provided as an impurity region for controlling a threshold voltage of the vertical transistor of the ground selection transistor. Under the surface of the substrate 100, facing the second word line structure 178, an n-type impurity region 190 may be provided. The vertical memory device may further include a CSL 164 and a bit line (not illustrated).

Hereinafter, the ground selection transistor including the second word line structure will be explained in more detail.

The metal layer 174 included in the second word line structure 178 may include a portion facing the surface of the substrate 100 and a portion facing the sidewall of the semiconductor pattern 132, respectively. Here, the part of the substrate 100, facing the metal layer 174 may be a first channel region 182, which may be a horizontal channel region, and the portion facing the sidewall of the semiconductor pattern 132 may be a second channel region 184, which may be a vertical channel region. In addition, the pad oxide layer 102 may be provided as the gate insulating layer of the planar transistor E.

The first channel region 182 may be a doped state of the n-type impurities. That is, an n-type impurity region 190 may be provided in the first channel region 182. The n-type impurity region 190 provided in the first channel region may be provided to decrease the threshold voltage of the planar transistor and to maintain a turn-on state all the time. That is, different type impurities may be doped into the first channel region 182 from the impurity region 168a for controlling the threshold voltage. In addition, the same impurity type as the conductive type of the impurities of the CSL may be doped into the first channel region 182.

In this case, the n-type impurity region 190 may have an impurity concentration lighter than the n-type impurities in the CSL 164. The CSL 212 makes contact with the first channel region 182 by the provision of the n-type impurity region 190.

The second channel region 184 may be a doped state of the p-type impurities. That is, the p-type impurity region 168a may be provided in the second channel region 184. The p-type impurity region 168a may be provided as an impurity region for controlling the threshold voltage to control the threshold voltage of the ground selection transistor.

Therefore, the planar transistor E including the horizontal channel region in the ground selection transistor may become a turn-on state and may be provided as a pass transistor. Differently, the vertical transistor F including the vertical channel region in the ground selection transistor may have a target threshold voltage and may be provided as a selection transistor substantially functioning as a switch.

In example embodiments, when the ground selection transistor is a PMOS transistor, an n-type impurity region 168a may be provided in the second channel region 184. In this case, the n-type impurity region 168a may be provided as an impurity region for controlling the threshold voltage to control the threshold voltage of the ground selection transistor. In addition, a p-type impurity region may be provided in the first channel region 182.

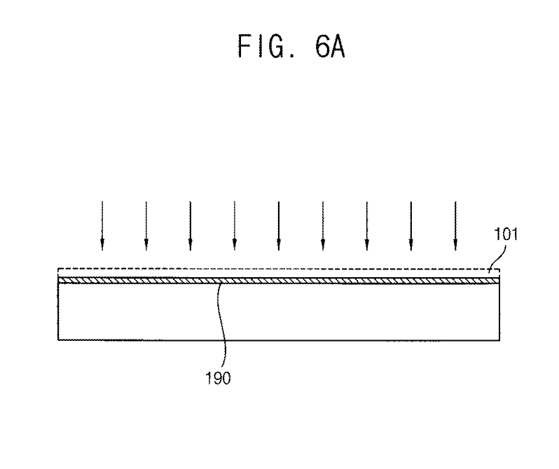

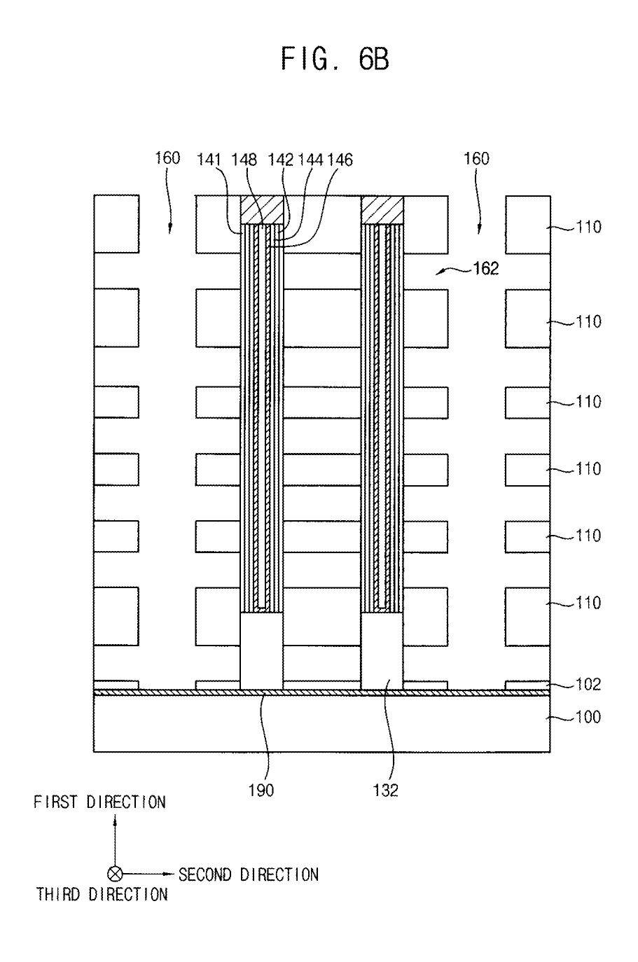

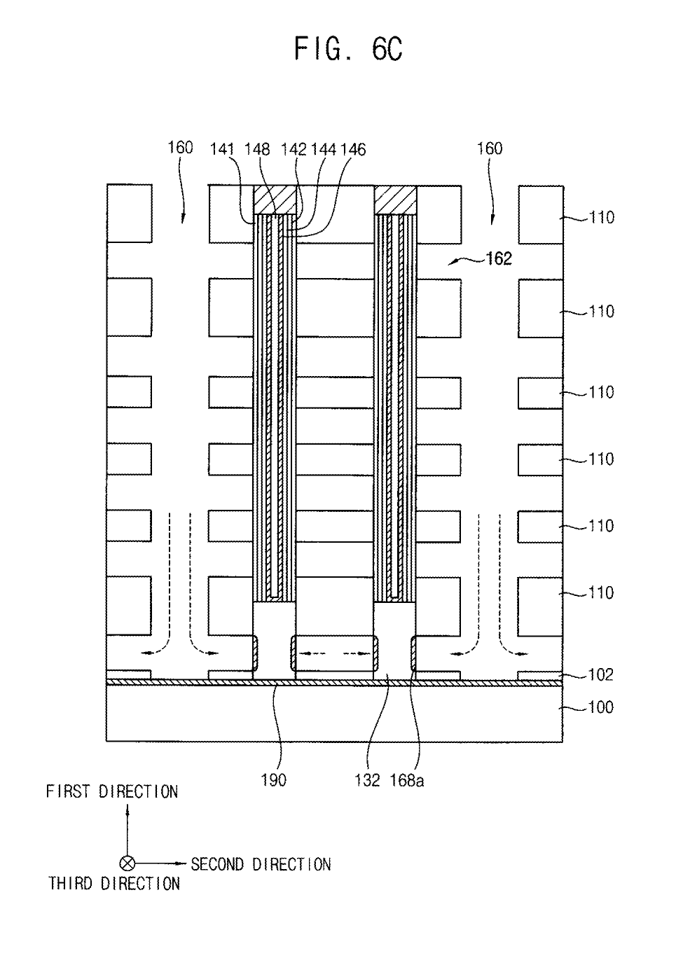

FIGS. 6A to 6C are cross-sectional views illustrating a method of manufacturing the vertical type semiconductor device in FIGS. 4 and 5.

Referring to FIG. 6A, a buffer oxide layer 101 may be formed on a substrate 100.

The substrate 100 may include a semiconductor material such as silicon, germanium, etc. The buffer oxide layer 101 may be formed to restrain the damage of the surface of the substrate during conducting an impurity doping process.

N-type impurities may be lightly doped into the surface of the substrate 100 including the buffer oxide layer 101 formed thereon. A lightly doped n-type impurity region 190 may be formed under the surface of the substrate 100. Then, the buffer oxide layer 101 may be removed.

Referring to FIG. 6B, the same processes may be conducted as explained above referring to FIGS. 3A to 3E with respect to the substrate 100 including the n-type impurity region 190.

Through conducting the above-described processes, a gap 162 may be formed between insulating interlayers 110 as illustrated in FIG. 6B. In the gap between the insulating interlayers 110, sacrificial oxide layers 141 may be exposed. In addition, the outer wall of a semiconductor pattern 132 may be exposed through the gap 162.

The ground selection transistor may include a first channel region in the horizontal direction of the surface of the substrate 100 under the pad oxide layer 102 and a second channel region in the vertical direction of the sidewall portion of the semiconductor pattern 132. Accordingly, the ground selection transistor may have a connection structure of a planar transistor including the first channel region and a vertical transistor including the second channel region. Here, the exposed portion of the semiconductor pattern may become the second channel region, which may be a vertical direction channel region of the ground selection transistor.

Referring to FIG. 6C, p-type impurities may be doped into the surface of the semiconductor pattern 132 exposed to the gap 162. The doping process of the p-type impurities may be the same as the explanation given referring to FIG. 3F.

Through doping the p-type impurities into the surface of the semiconductor pattern, a p-type impurity region 168a may be formed in the second channel region of the ground selection transistor. Through the channel doping, the threshold voltage of the vertical transistor part in the ground selection transistor may be controlled.

An n-type impurity region may be formed in the first channel region of the planar transistor part in the ground selection transistor. Accordingly, the planar transistor may maintain a turn-on state and may be provided as a pass transistor.

An example where the ground selection may be an NMOS transistor has been explained. Alternatively, the ground selection transistor may be a PMOS transistor. In this case, n-type impurities may be doped as impurities for controlling the threshold voltage.

Then, the same processes explained referring to FIG. 3G and FIG. 1 may be conducted to complete the vertical type semiconductor device illustrated in FIG. 4.

According to example embodiments, the threshold voltage of the ground selection transistor may be controlled through a more simplified process. Thus, the manufacturing process of a vertical type non-volatile memory device may be simplified.

### Comparative Experiment

A gas phase doping process was conducted with respect to each of the samples and a comparative sample to dope impurities, and an impurity doping profile was measured. The impurity doping profile was measured as a calculation value by a simulation.

When a ground selection transistor is formed in the semiconductor pattern, a substantial channel region of the ground selection transistor may be the surface of the semiconductor pattern. In order to obtain good threshold voltage characteristic and operating characteristic of the ground selection transistor, preferred doping profile in the semiconductor pattern may be as follows. The profile may preferably have a relatively high impurity concentration at the surface of the semiconductor pattern, provided as a substantial channel region of the ground selection transistor, and may preferably have a gradually decreasing impurity concentration into the semiconductor pattern. When the doping profile is uniform at the surface and inner portion of the semiconductor pattern, the threshold voltage characteristic and the operating characteristic of the ground selection transistor may be bad. In addition, the dispersion of the threshold voltage of the ground selection transistor may be generated, and the forming of the transistor having a target threshold voltage may become disadvantageous.

### Sample 1

In the structure as illustrated in FIG. 3F, a gas phase doping process was conducted with the first doping condition. Then, a heat treating process was conducted to diffuse the doped impurities at 850° C. for 30 minutes.

### Sample 2

In the structure as illustrated in FIG. 3F, a gas phase doping process was conducted with the second doping condition. The target impurity concentration of the surface of the semiconductor pattern was lower in the second doping condition than in the first doping condition. Then, a heat treating process was conducted to diffuse the doped impurities at 850° C. for 30 minutes.

### Sample 3

In the structure as illustrated in FIG. 3F, a gas phase doping process was conducted with the third doping condition. The target impurity concentration of the surface of the semiconductor pattern was lower in the third doping condition than in the second doping condition. Then, a heat treating process was conducted to diffuse the doped impurities at 850° C. for 30 minutes.

### Comparative Sample

In the structure as illustrated in FIG. 3F, a gas phase doping process was not conducted with respect to the surface of the semiconductor pattern.

Each of an impurity concentration according to positions of the semiconductor pattern was measured for Samples 1 to 3 and Comparative Sample.

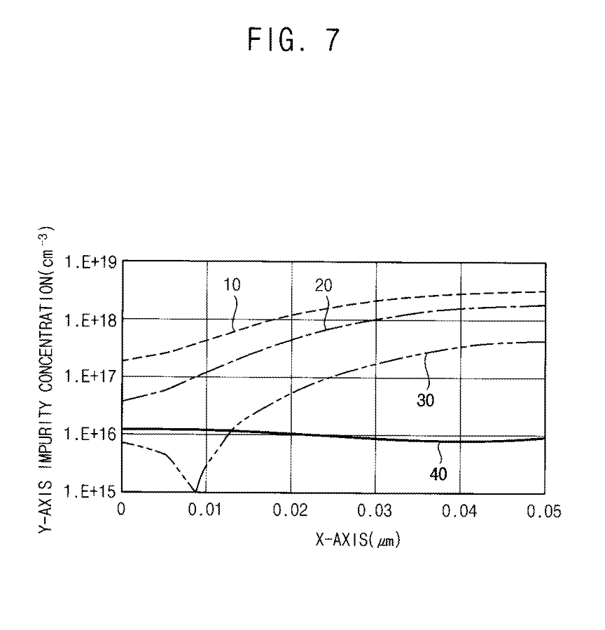

FIG. 7 is a graph illustrating impurity concentrations according to positions of a semiconductor pattern for Samples 1 to 3 and Comparative Sample.

In FIG. 7, coordinates on x-axis represent the position in the cross-sectional view of the semiconductor pattern in the x-axis direction. Coordinate 0 on the x-axis represents the central portion of the cross-section of the semiconductor pattern and coordinate 0.05 on the x-axis represents the edge portion of the cross-section of the semiconductor pattern. That is, coordinate 0 of the x-axis represents the inner central portion of the semiconductor pattern, and coordinate 0.05 of the x-axis represents the surface portion of the semiconductor pattern.

In FIG. 7, reference numeral 10 represents the doping profile of Sample 1, reference numeral 20 represents the doping profile of Sample 2, reference numeral 30 represents the doping profile of Sample 3, and reference numeral 40 represents the doping profile of Comparative Sample.

Referring to FIG. 7, doping profiles having a similar shape may be obtained even though the gas phase doping process for each sample was conducted under different conditions such as for Samples 1 to 3.

That is, the surface portion of the semiconductor pattern may have a high impurity concentration in Samples 1 to 3. In addition, the inner portion of the semiconductor pattern may have a lighter impurity concentration than the surface portion of the semiconductor pattern. That is, the impurity concentration may be decreased according to the depth of the semiconductor pattern from the surface portion. As described above, the surface portion of the semiconductor pattern provided as the substantial channel region of the ground selection transistor may have a relatively high impurity concentration, and the inner portion of the semiconductor pattern may have a relatively light impurity concentration when comparing with the surface portion thereof. Therefore, a ground selection transistor having a high performance and a target threshold voltage may be formed in accordance with example embodiments.

As described above, in example embodiments, a vertical type semiconductor device may be formed by a simplified process in accordance with example embodiments. The vertical type semiconductor device may be used in various electronic products and telecommunication products.

The foregoing is illustrative of example embodiments and is not to be construed as limiting thereof. Although a few example embodiments have been described, those skilled in the art will readily appreciate that many modifications are possible in example embodiments without materially departing from the spirit and scope of claims.

What is claimed is:

1. A method of manufacturing a vertical type semiconductor device comprising:
alternately stacking a plurality of sacrificial layers and a plurality of insulating interlayers on a substrate;
forming a pillar structure that penetrates the plurality of sacrificial layers and the plurality of insulating interlayers,
the pillar structure contacting an upper surface of the substrate,
the pillar structure including a semiconductor pattern and a channel pattern;
forming gaps by selectively removing the plurality of sacrificial layers and portions of the plurality of insulating interlayers to expose sidewalls of the semiconductor pattern and the channel pattern;
forming an impurity region by doping impurities under a surface of the semiconductor pattern that is exposed by one of the gaps;
forming a first word line structure in a different one of the gaps
the first word line structure facing the channel pattern and surrounding the pillar structure;
forming a second word line structure in the one of the gaps,
the second word line structure having one side facing the semiconductor pattern and another side facing the substrate,
the second word line surrounding the pillar structure; and
forming a common source line at a portion of the substrate that is adjacent to a sidewall end portion of the second word line structure.

2. The method of claim 1, wherein the forming the common source line includes doping impurities into the portion of the substrate that is adjacent to the sidewall end portion of the second word line structure.

3. The method of claim 2, wherein a conductivity type of the impurities in the impurity region is opposite a conductivity type of the impurities in the common source line.

4. The method of claim 3, wherein
the forming the impurity region by doping impurities includes doping p-type impurities under the surface of the semiconductor pattern, and
the doping impurities of the forming the common source line includes doping n-type impurities into the portion of the substrate.

5. The method of claim 1, further comprising:
doping impurities under apart of the substrate facing the second word line structure,
wherein the impurities under the part of the substrate have a different conductivity type than a conductivity type of the impurities in the impurity region of the semiconductor pattern.

6. The method of claim 1, wherein the forming the impurity region by doping impurities includes a gas phase doping process.

7. A vertical type semiconductor device comprising:
a substrate;
a pillar structure on the substrate,
the pillar structure including a semiconductor pattern and a channel pattern,
the semiconductor pattern including an impurity region under a surface of the semiconductor pattern,
the impurity region being configured to control a threshold voltage of a transistor;
a first word line structure facing the channel pattern and extending horizontally while surrounding the pillar structure;
a second word line structure surrounding the pillar structure,
the second word line structure including one side facing the impurity region of the semiconductor pattern and another side facing the substrate; and
a common source line at a portion of the substrate that is adjacent to a sidewall end portion of the second word line structure.

8. The semiconductor device of claim 7, wherein a conductivity type of the impurity region is opposite a conductivity type of impurities in the common source line.

9. The semiconductor device of claim 7, further comprising: one of an undoped region and an impurity doped region under a surface of the substrate,
the one of the undoped region and the impurity doped region facing the second word line structure,
wherein a conductivity type of the impurity doped region is the same as a conductivity type as the impurity region in the semiconductor pattern.

10. The semiconductor device of claim 7, further comprising: an impurity doped region having an opposite conductivity type of the impurity region, wherein the impurity doped region is under the surface of the substrate and faces the second word line structure.

11. A vertical type semiconductor device comprising:
a substrate including a common source line (CSL);
a pillar extending vertically from a portion of the substrate,
the pillar including a channel pattern on a semiconductor pattern,
the semiconductor pattern including an impurity region at a sidewall,
the impurity region and the CSL having opposite conductivity types; and
a plurality of word line structures and insulating interlayers alternately stacked on a part of the substrate that is between the portion of the substrate and the CSL,
the plurality of word line structures including a first word line structure extending horizontally from a sidewall of the channel pattern,
the plurality of word line structures including a second word line structure that extends horizontally from the impurity region of the semiconductor pattern over a part of the substrate that is between the CSL and the portion of the substrate.

12. The vertical type semiconductor device of claim 11, further comprising:
a pad oxide layer, wherein
the second word line structure is on the pad oxide layer,
the second word line structure includes a metal layer and a dielectric layer,
the dielectric layer is between the metal layer and the impurity region of the semiconductor pattern,
the metal layer is configured as a gate of a vertical transistor that includes the impurity region of the semiconductor pattern as a channel, and
the metal layer is configured as a gate of a planar transistor that includes the part of the substrate as a channel region.

13. The vertical type semiconductor device of claim 11, wherein
the substrate further includes an impurity doped region that extends into the portion of the substrate and the part of the substrate, and
a conductivity type of the impurity doped region is opposite the conductivity type of the impurity region in the semiconductor pattern.

14. The vertical type semiconductor device of claim 11, wherein the substrate further includes an undoped impurity doped region that extends into the portion of the substrate and the part of the substrate.

15. The vertical type semiconductor device of claim 11, wherein the substrate further includes a doped impurity doped region that extends into the portion of the substrate and the part of the substrate, and a conductivity type of the impurity doped region is the same as the conductivity type of the impurity region in the semiconductor pattern.

16. The vertical type semiconductor device of claim 15, wherein an impurity concentration of the impurity doped region is lighter than that of the impurity region in the semiconductor pattern.

17. The vertical type semiconductor device of claim 11, wherein the impurity region is positioned at a surface portion of the semiconductor pattern.

18. The vertical type semiconductor device of claim 11, wherein an impurity concentration of a surface portion of the semiconductor pattern is higher than that of an inner portion of the semiconductor pattern.

19. The vertical type semiconductor device of claim 11, further comprising:
a pad on the on channel pattern, wherein
the first word line structure is a string selection line, and
the plurality of word line structures include other word line structures between the first word line structure and the second word line structure.

20. The vertical type semiconductor device of claim 19, further comprising:
a charge storing layer surrounding the channel pattern; and
a tunnel insulating layer surrounding the charge storing layer, wherein
the tunnel insulating layer is between the channel pattern and other word line structures.
